(19) United States
(12) Patent Application Publication
(10) Pub. No.: US 2002/0127818 A1
(43) Pub. Date: Sep. 12, 2002

(54) Recess-free trench isolation structure and method of forming the same

(76) Inventors: Jung-II Lee, Kimchun-shi (KR); Dong-Ho Ahn, Suwon (KR)

Correspondence Address: JONES VOLENTINE, P.L.L.C., Suite 150, 12200 Sunrise Valley Drive, Reston, VA, 20191, US

(21) Appl. No.: 10/079,363

(22) Filed: Feb. 21, 2002

(30) Foreign Application Priority Data
Mar. 2, 2001 (KR) 2001-10846

(51) Int. Cl. H01L 21/76

(52) U.S. Cl. 438/424

(57) ABSTRACT

A trench isolation structure and method of forming the trench isolation structure, in which a recess-preventing insulator layer is formed at least between a pad nitride layer and a trench-burying insulator layer. In the method and resulting structure, the etch resistivity of the recess-preventing insulator layer is higher than that of the trench-burying insulator layer. Therefore, the etch rate of the recess-preventing insulator layer is lower than that of the trench-burying insulator layer.

This application relies for priority upon Korean Patent Application No. 2001-10846, filed on Mar. 2, 2001, the contents of which are herein incorporated by reference in their entirety.

### BACKGROUND OF THE INVENTION

1. Field of the Invention

The present invention generally relates to a semiconductor device and a method of fabricating the same. More specifically, the present invention is directed to a recess-free trench isolation structure and a method of forming the same.

2. Description of the Related Art

The elements of a semiconductor device are becoming more densely integrated to improve the processing speed and increase the memory capacity of the resulting devices. The technology required for isolating elements and devices formed on a semiconductor substrate is fundamental to device construction, and it has a enormous influence on the resulting transistor characteristics and device reliability.

Poor device isolation results in an increase in leakage current, which causes a considerable loss of power supplied to a semiconductor chip. Also, a phenomenon know as latch-up is heightened, which may result in temporary or permanent deterioration of the operation of the semiconductor device. Furthermore, it may result in voltage shift, cross talk, or a degradation of the noise margin.

A technology know as local oxidation of silicon (LOCOS) has been used for isolating a device region on a semiconductor substrate. In such a procedure, a patterned silicon nitride layer and a pad oxide layer (used for alleviating a stress created by the silicon nitride layer) are used to implant ions into an isolation region, and then a thin field oxide layer is locally formed to complete the typical LOCOS structure.

However, the LOCOS structure suffers certain drawbacks, including the formation know as a bird's beak, and a resulting physical channel that is smaller than a predetermined channel in width. To overcome these problems, a shallow trench isolation (STI) technique has been used.

In general, the STI technique includes the steps of etching a semiconductor substrate using a trench etching mask to form a trench, filling the trench with a chemical vapor deposition (CVD) insulating layer (device isolation layer), planarizing the CVD insulating layer, and then removing the trench etching mask.

A drawback to the conventional STI technique is that it creates recesses, in which a portion of the trench isolation material or an underlying nitride liner is excavated inwardly toward the trench around the upper edge of the trench. This recess creation phenomenon will be described with reference to FIGS. 1A-1B and FIGS. 2A-2B.

Referring to FIG. 1A, a pad oxide layer 202 and a pad nitride layer 204 are formed on a semiconductor substrate 200. The layers 202 and 204 and the substrate 200 are then patterned and etched to form a trench in the substrate 200. A trench thermal oxide layer 208 is formed along the sidewall and bottom of the trench in order to alleviate any damage caused by the trench-etching procedure. An insulating material layer 214 is formed via a CVD method to fill up the trench. Using the pad nitride layer 204 as a planarizing-stop layer, the material layer 214 is then planarized. The pad nitride layer 204 is then removed using a wet etchant such as, for example, phosphoric acid. In a subsequent cleaning process, the pad oxide layer 202 is removed to complete the trench isolation structure.

However, during this typical trench formation procedure, a portion of the material layer 214 is excavated inwardly toward the trench (i.e., a recess 218 is created) at an upper edge of the trench isolation structure, as shown in the dashed circle of FIG. 1B. This is because the material layer 214, which has a high wet-etch rate and is in contact with the pad nitride layer 204, is partially etched at the same time as the pad nitride layer 204 and the pad oxide layer 202 are removed by the wet etchant. The recess 218 causes a decrease in the threshold voltage of the transistor, while increasing the leakage current, both of which are undesirable results.

FIGS. 2A-2B differ from FIGS. 1A-1B in that a nitride liner 210 is first formed on the trench thermal oxide layer 208 in order to prevent oxidation of the trench inner wall. Similarly to FIG. 1A, after the nitride liner 210 is formed on the trench thermal oxide layer 208, a CVD insulating material layer 214 is formed on the nitride liner 210 to fill up the trench. After the planarization process is carried out, the pad nitride layer 204 is removed by a phosphoric acid solution during a wet etch procedure. The pad oxide layer 202 is thereafter removed through a cleaning process to complete the trench isolation structure.

As can be seen in FIG. 2B, a larger recess 218′ (compared to the recess 218 of FIG. 1B) is created at the upper edge of the trench isolation structure. This is because the nitride liner 210 is made of the same material as the pad nitride layer 204, and thus both the nitride liner 210 and the CVD insulating material layer 214 are etched inwardly toward the trench. In this case, in addition to the typical recess formation 218 as shown in FIG. 1B, the CVD insulating material layer 214 is further etched in the area exposed as a result of the etching of the nitride liner 210. This results in the formation of a larger recess 218′.

### SUMMARY OF THE INVENTION

In view of the problems present in the conventional art, it is an object of the invention to provide a recess-free trench isolation structure.

Another object of the present invention is to provide a method of forming a recess-free trench isolation structure.

Accordingly, to achieve the above objects, there is provided a structure and method of forming a trench isolation structure in which a recess-preventing insulator layer is formed at least between a pad nitride layer and a trench-burying insulator layer. In the method and resulting structure, the etch resistivity of the recess-preventing insulator layer is higher than that of the trench-burying insulator layer (i.e., the etch rate of the recess-preventing insulator layer is lower than that of the trench-burying insulator layer). The recess-preventing insulator layer is preferably made of a material that is in the same group as the trench-burying insulator layer, in order to improve the interfacial characteristics between the recess-preventing insulator layer and the trench-burying insulator layer. For example, if the trench-burying insulator layer is made of chemical vapor deposition (CVD) oxide, the recess-preventing insulator layer is made of a densified thermal oxide that has a higher etch resistivity relative to the CVD oxide.

More specifically, after forming the trench, a silicon layer is formed and thermally oxidized to form the recess-preventing insulator layer having a thickness of 50 Å to 500 Å. The thermal oxidation process is carried out at a temperature of 800° C. to 1000° C. in an H₂O or O₂ ambient. The silicon layer may be formed of amorphous silicon or polycrystalline silicon (polysilicon).

Because it is interposed between the pad nitride layer and the trench-burying insulator layer, the recess-preventing insulator layer protects the trench-burying insulator layer while the pad nitride layer is being removed with the wet etchant. Accordingly, this prevents the recess from forming in the trench-burying insulator layer at an upper edge of the trench.

If a nitride liner is formed prior to formation of the trench-burying insulator layer so as to prevent oxidation of the trench inner wall, the recess-preventing insulator may be formed between the nitride liner and the trench-burying insulator layer. In this embodiment, etching of the trench-burying insulator layer is prevented by the recess-preventing insulator layer, which minimizes the surface area of the nitride liner exposed to the etchant of the pad nitride layer. Accordingly, the nitride liner is minimally etched.

Alternatively, the nitride liner may be formed after the formation of the recess-preventing insulator layer. That is, the trench-burying insulator layer is formed following the sequential formation of the recess-preventing insulator layer and the nitride liner. Accordingly, the recess-preventing insulator layer is interposed between the pad nitride layer and the nitride liner, protecting the nitride liner from the etchant used to remove the pad nitride layer.

According to the present invention, a recess-preventing insulator layer protects a trench-burying insulator layer and a nitride liner. This eliminates the need to carry out a high temperature (1000° C. to 1200° C.) annealing process for densifying a trench-burying insulator layer. Therefore, the semiconductor substrate need not be subjected to such a high temperature process, which enhances the reliability of the device, as well as shortens the production cycle and reduces costs by eliminating a process step.

### BRIEF DESCRIPTION OF THE DRAWINGS

The above objects and advantages of the present invention will become more apparent by describing in detail a preferred embodiment thereof with reference to the attached drawings in which:

FIGS. 1A and 1B are cross-sectional views of a semiconductor substrate showing a recess created around an upper edge of a trench during a conventional method of forming a trench isolation;

FIGS. 2A and 2B are cross-sectional views of a semiconductor substrate showing a recess created around an upper edge of a trench during another conventional method of forming a trench isolation;

FIGS. 3A through 3F are cross-sectional views of a semiconductor substrate showing the steps of forming a trench isolation structure according to a first embodiment of the present invention;

FIGS. 4A through 4E are cross-sectional views of a semiconductor substrate showing the steps of forming a trench isolation structure according to a second embodiment of the present invention;

FIGS. 5A through 5D are cross-sectional views of a semiconductor substrate showing the steps of forming a trench isolation structure according to a third embodiment of the present invention; and

FIGS. 6A through 6E are cross-sectional views of a semiconductor substrate showing the steps of forming a trench isolation structure according to a fourth embodiment of the present invention.

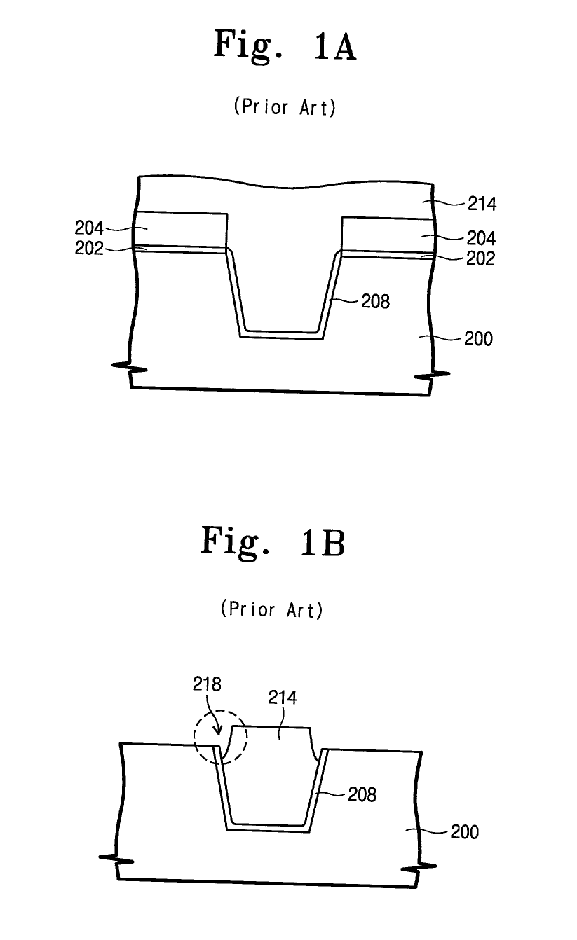

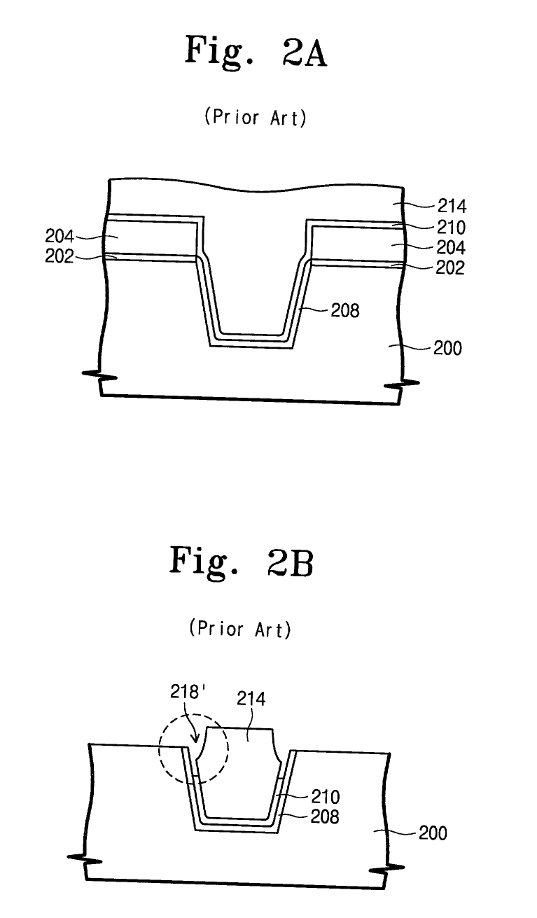

### DESCRIPTION OF PREFERRED EMBODIMENTS

The present invention will now be described more fully with reference to the accompanying drawings, in which a preferred embodiment of the invention is shown. This invention may, however, be embodied in many different forms and should not be construed as being limited to the embodiments set forth herein. Rather, the embodiments are provided so that this disclosure will be thorough and complete, and will fully convey the concept of the invention to those skilled in the art. In the drawings, the thickness of a layer or region are exaggerated for clarity. It will also be understood that when a layer is referred to as being “on” another layer or substrate, it can be directly on the other layer or substrate, or intervening layers may also be present.

### First Embodiment

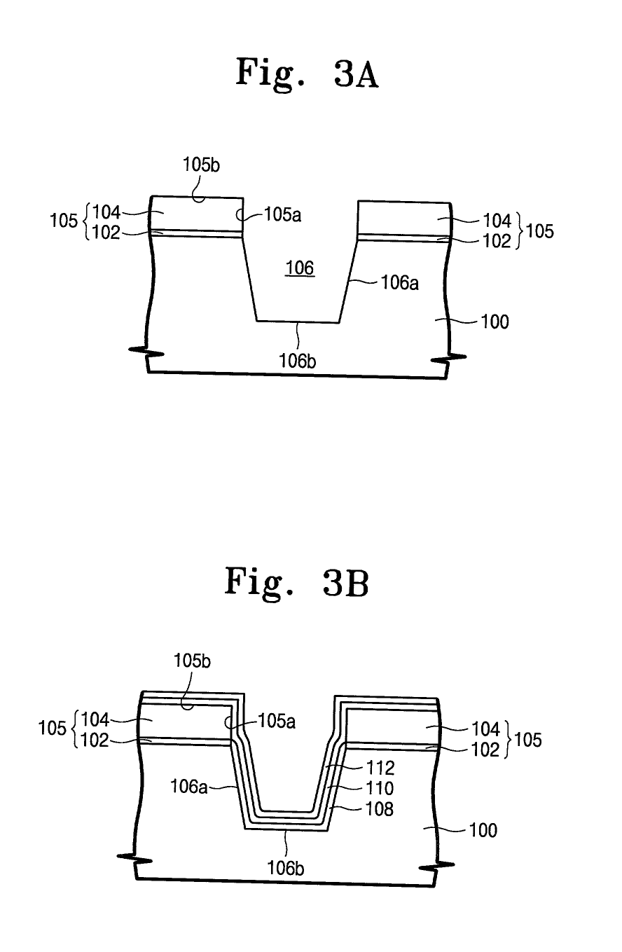

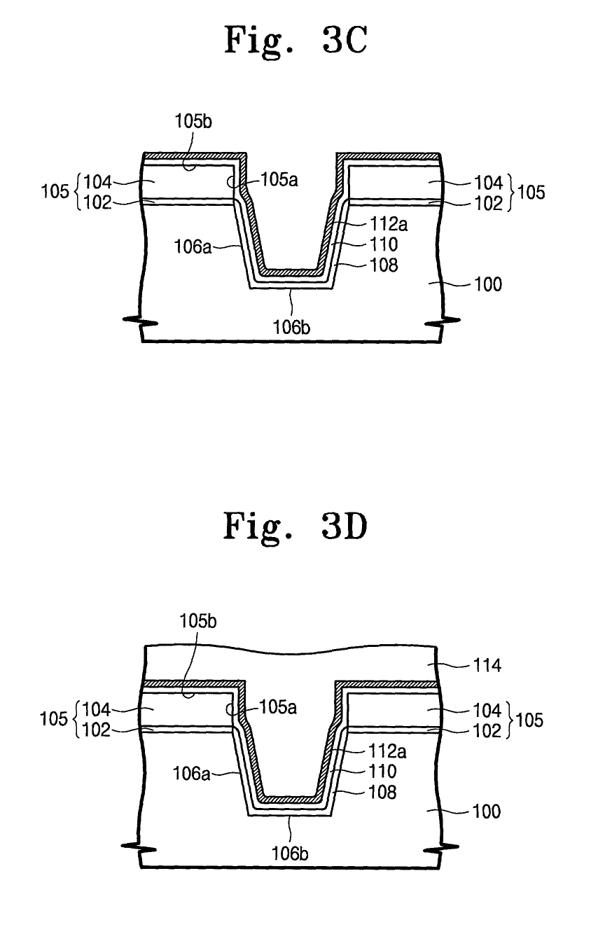

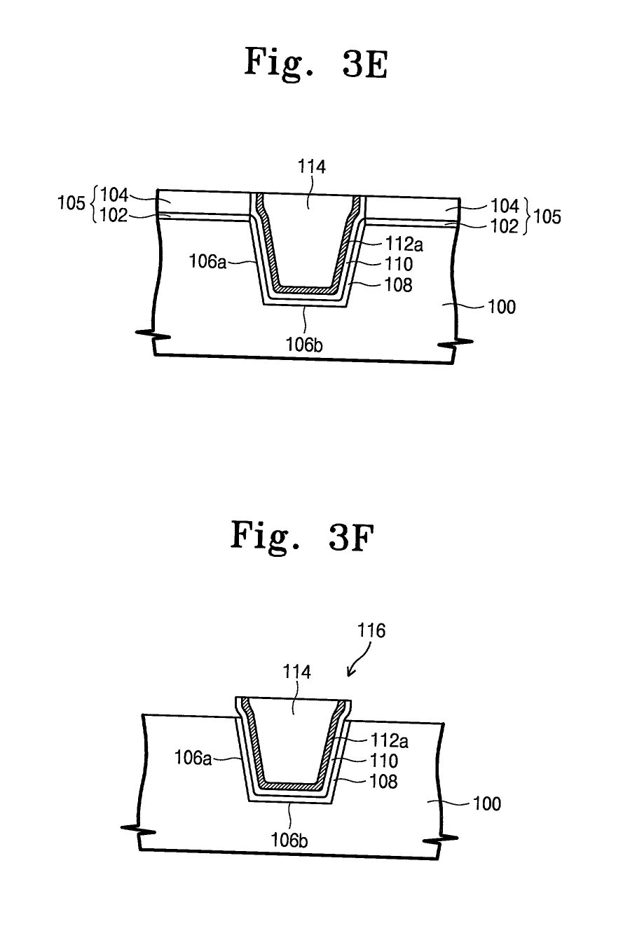

Referring to FIG. 3A, a trench etch mask 105 is formed on a semiconductor substrate 100. The trench etch mask 105 comprises a pad oxide layer 102 to define an active region, and a pad nitride layer 104. More specifically, the pad oxide layer 102 is formed on the substrate 100 by, for example, a thermal oxidation technique. The pad nitride layer 104 is then formed on the pad oxide layer 102 by, for example, a chemical vapor deposition (CVD) technique. The pad nitride layer 104 may be used as a planarization-stop layer in the subsequent trench isolation planarization process. Using conventional photolithography and etching processes, the pad nitride layer 104 and the pad oxide layer 102 are patterned to form the trench etch mask 105. As a result, the etching of the trench etch mask 105 defines a trench etch mask sidewall 105a and a trench etch mask top surface 105b.

The trench etch mask 105 is used to etch the exposed substrate 100 to a predetermined depth, thereby forming a trench 106 that consists of a trench sidewall 106a and a trench bottom 106b. The portion of the substrate 100 covered by the patterned trench etch mask 105 is the active region.

Referring now to FIG. 3B, a trench thermal oxidation process is carried out in order to alleviate any damage caused by etching the semiconductor substrate 100. The thermal oxidation process results in the formation of a trench thermal oxide layer 108 within the trench 106 (i.e., the trench thermal oxide layer 108 is formed on the trench sidewall 106a and trench bottom 106b of the trench 106). Note that the implementation of the trench thermal oxidation process is entirely discretionary, and therefore it may be skipped.

When the trench thermal oxide layer 108 is formed, a nitride liner 110 is then formed on the trench thermal oxide layer 108 so as to prevent internal oxidation of the trench 106. A silicon layer 112 is formed on the nitride liner 110, and is then thermally oxidized to form a first or upper recess-preventing insulator layer 112a (see FIG. 3C). Note that “upper” in this case refers to a layer formed on top of the nitride layer 110. Later in the discussion a second or lower recess-preventing will be introduced, and in that case, “lower” refers to a layer formed under the nitride layer

A method of forming the upper recess-preventing insulator layer 112a will now be described in detail. First, an amorphous silicon layer 112 is formed to a thickness of 50 Å to 300 Å. Then, a thermal oxidation process is carried out to form a trench thermal oxide layer to a thickness of 50 Å to 500 Å. The thermal oxidation process is carried out at a temperature of 800° C. to 1000° C. in an H₂O or O₂ ambient so that the amorphous silicon layer is converted or transformed into an oxide layer. Alternatively, a polysilicon layer may be used instead of the amorphous silicon, and the polysilicon layer is then thermally oxidized under substantially the same conditions to form a trench thermal oxide layer.

The upper recess-preventing insulator layer 112a is made of insulator that has a lower etch rate (i.e., a higher etch resistivity) relative to a later formed trench-burying insulator 114 (described below), with respect to an etchant used to subsequently etch the pad nitride layer 104.

Referring to FIG. 3D, a trench-burying insulator layer 114 is formed on the upper recess-preventing insulator layer 112a. The trench-burying insulator layer 114 is made of CVD oxide. In this configuration, therefore, the upper recess-preventing insulator layer 112a is interposed between the CVD oxide layer (trench-burying insulator layer 114) and the pad nitride layer 104. This makes it possible to skip a high temperature (1000° C. to 1200° C.) annealing process for densifying the trench-burying insulator layer 114. This is because the upper recess-preventing insulator layer 112a protects the CVD oxide layer (trench-burying insulator layer 114) from the etchant used to etch the pad nitride layer 104, which in turn prevents the creation of a recess at the upper edge of the trench 106.

Preferably, the upper recess-preventing insulator layer 112a and the trench-burying insulator layer 114 are comprised of oxide materials in the same group to improve the interfacial characteristics therebetween. The upper recess-preventing insulator layer 112a is preferably made of thermal oxide in which a silicon layer is oxidized. Since the upper recess-preventing insulator layer 112a is more densified relative to the trench-burying insulator layer 114, the upper recess-preventing insulator layer 112a has a lower etch rate (i.e., a higher etch resistivity) relative to the trench-burying insulator layer 114.

Referring now to FIG. 3E, the pad nitride layer 104 is used as a planarization-stop layer to perform a planarization process on the trench-burying insulator layer 114, such as, for example, a chemical mechanical polishing (CMP) process. The pad nitride layer 104 is then removed using a phosphoric acid solution. The pad oxide layer 102 is then removed in a subsequent cleaning process to form the recess-free trench isolation structure 116, as show in FIG. 3F.

According to the first embodiment of the present invention, the trench isolation structure 116 includes a trench thermal oxide layer 108 formed on the trench sidewall 106a and trench bottom 106b, a nitride liner 110 formed on the trench thermal oxide layer 108, an upper recess-preventing insulator layer 112a formed on the nitride liner 110, and a trench-burying insulator layer 114 formed on the recess-preventing insulator layer 112a to fill up the trench.

Referring to FIG. 3D, the upper recess-preventing insulator layer 112a having a low etch rate is interposed between the pad nitride layer 104 and the CVD oxide trench-burying insulator layer 114. Therefore, the CVD oxide layer is minimally attacked by an etchant (e.g., a phosphoric acid solution) used to remove the pad nitride layer 104. Also, the area of the nitride liner 110 exposed to the phosphoric acid solution is reduced, which prevents creation of a larger recess at the CVD oxide trench-burying insulator layer 114 and the nitride liner 110.

### Second Embodiment

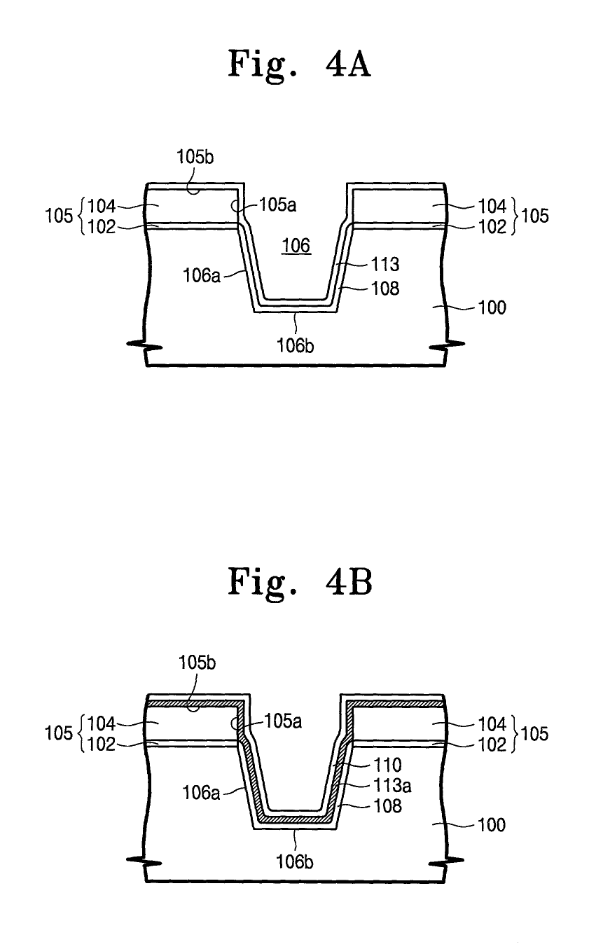

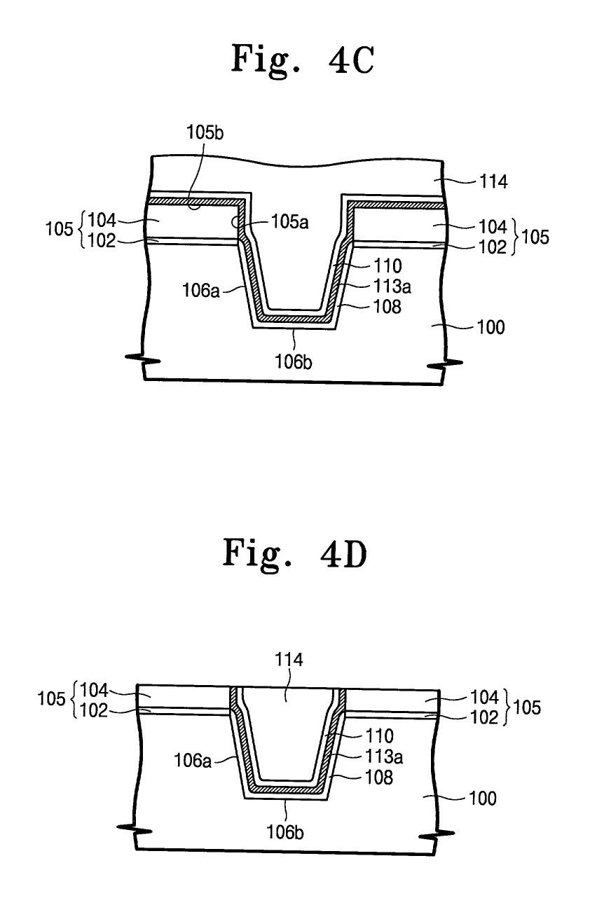

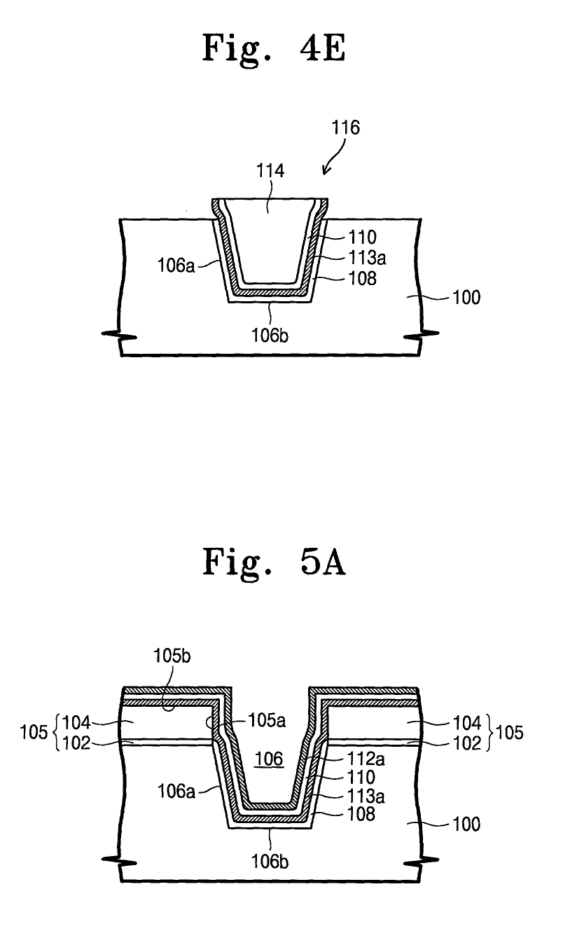

A second embodiment of the present invention will now be described hereinafter with reference to FIGS. 4A through 4E, in which the same numerals denote the same elements as the first embodiment. For simplicity, a description of these same elements will be skipped where appropriate.

Generally, the second embodiment differs from the first embodiment in that the upper recess-preventing insulator layer is formed prior to formation of the nitride liner. The upper recess-preventing insulator layer is thus interposed between the pad nitride layer and the nitride liner, thereby separating the nitride layers from each other. This makes it difficult for the etchant for the pad nitride layer to penetrate the nitride liner.

Referring to FIG. 4A, a semiconductor substrate 100 is etched using a trench etch mask 105 to form a trench 106, similar to the first embodiment. The trench etch mask is composed of a pad oxide layer 102 and a pad nitride layer 104. A trench thermal oxidation process is carried out in order to alleviate any damage caused by etching the semiconductor substrate 100. The thermal oxidation process results in the formation of a trench thermal oxide layer 108 within the trench 106 (i.e., the trench thermal oxide layer 108 is formed on the trench sidewall 106a and trench bottom 106b of the trench 106). Note that the implementation of the trench thermal oxidation process is entirely discretionary, and therefore it may be skipped.

A lower silicon layer 113 is formed and preferably thermally oxidized to form the lower recess-preventing insulator layer 113a as shown in FIG. 4B. In the case where the trench thermal oxide layer 108 is not formed, the thermal oxidation process for forming the lower recess-preventing insulator layer 113a would alleviate some of the etch-damage.

A nitride liner 110 is then formed on the lower recess-preventing insulator layer 113a . With this configuration, the two nitride layers, pad nitride layer 104 and nitride liner 110, are not in contact with each other.

Referring now to FIG. 4C, a CVD oxide trench-burying insulator layer 114 is formed on the nitride liner 110 to fill up the trench. The formation of the lower recess-preventing insulator layer 113a makes it possible to skip a high temperature (1000° C. to 1200° C.) annealing process for densifying the trench-burying insulator layer 114.

Referring now to FIG. 4D, the pad nitride layer 104 is used as a planarization-stop layer to perform a planarization process on the trench-burying insulator layer 114, such as, for example, a chemical mechanical polishing (CMP) process. The pad nitride layer 104 is then removed using a phosphoric acid solution. The pad oxide layer 102 is then removed in a subsequent cleaning process to form the recess-free trench isolation structure 116, as show in FIG. 4E.

According to the second embodiment of the present invention, a trench isolation structure 116 includes a trench thermal oxide layer 108 formed on the trench sidewall 106a and trench bottom 106b, a lower recess-preventing insulator layer 113a formed on the trench thermal oxide layer 108, a nitride liner 110 formed on the lower recess-preventing insulator layer 113a, and a trench-burying insulator layer 114 formed on the nitride liner 110.

Because of the lower recess-preventing insulator layer 113a, the nitride liner 110 and the CVD oxide trench-burying insulator layer 114 do not directly contact the pad nitride layer 104. This makes it possible to prevent the phosphoric acid solution etchant for the pad nitride layer 104 from penetrating the nitride liner 110 and the CVD oxide trench-burying insulator layer 114.

### Third Embodiment

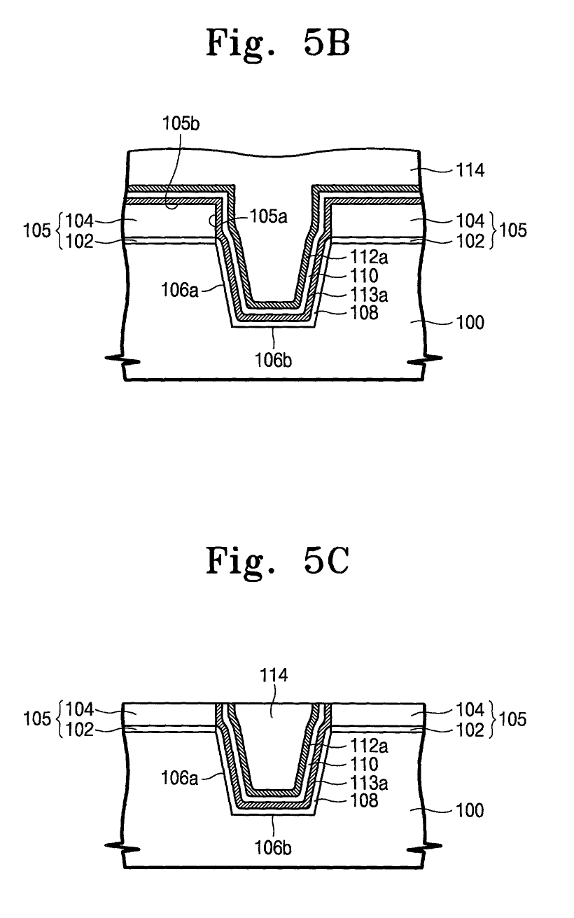

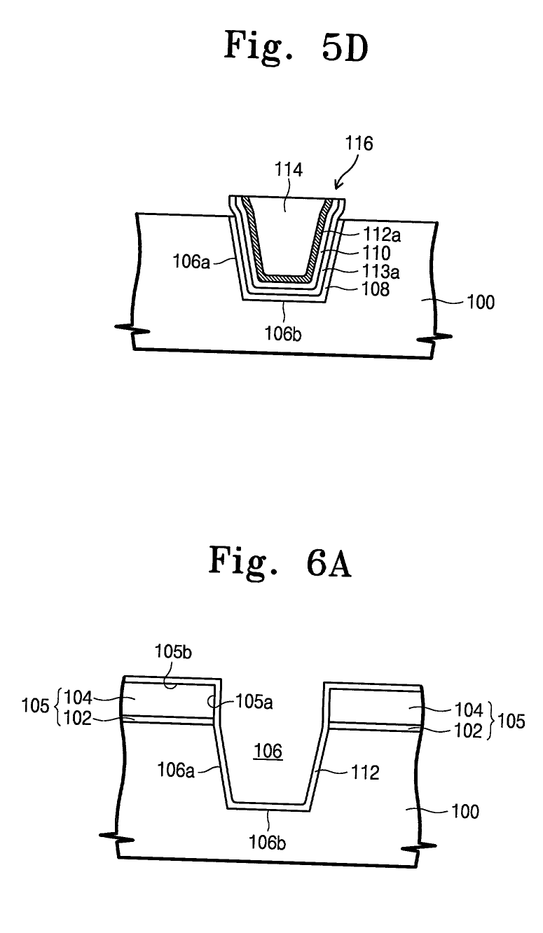

A third embodiment of the present invention will now be described hereinafter with reference to FIGS. 5A through 5D, in which the same numerals denote the same elements as the first embodiment. Thus, a description of the same elements will be skipped where appropriate.

In general, the third embodiment is different from the first embodiment in that two recess-preventing insulator layers are formed, both before and after the formation of the nitride liner. In other words, if an additional recess-preventing insulator layer was formed after the nitride liner as set forth and described in the second embodiment, one would achieve the resulting third embodiment. The nitride liner 110 is thus surrounded by an upper recess-preventing insulator layer 112a as described in the first embodiment, and a lower recess-preventing insulator layer 113a as described in the second embodiment. A trench-burying insulator layer 114 is then formed on the upper recess-preventing insulator layer 112a. This makes it possible to prevent the creation of a recess at the nitride liner 110 and the trench-burying insulator layer 114.

More specifically, referring now to FIG. 5A, a trench thermal oxide layer 108, a lower recess-preventing insulator layer 113a, and a nitride liner 110 are sequentially formed following formation of a trench 106, in the same manner as shown in FIG. 4B for the second embodiment. An upper recess-preventing insulator layer 112a is then formed on the nitride liner 110. Preferably, the recess-preventing insulator layers 112a and 113a are made of thermal oxide.

Referring now to FIG. 5B, a trench-burying insulator layer 114 composed of CVD oxide is formed on the upper recess-preventing insulator layer 112a to fill up the trench. Because of the presence of the recess-preventing insulator layers 113a and 112a, a high temperature annealing process is not necessary for the CVD oxide trench-burying insulator layer 114.

Referring now to FIG. 5C, the pad nitride layer 104 is used as a planarization-stop layer to perform a planarization process on the trench-burying insulator layer 114, such as, for example, a chemical mechanical polishing (CMP) process. The pad nitride layer 104 is then removed using a phosphoric acid solution. The pad oxide layer 102 is then removed in a subsequent cleaning process to form the recess-free trench isolation structure 116, as show in FIG. 5D.

According to the third embodiment, a trench isolation structure 116 includes a trench 106 formed in a semiconductor substrate 100, a trench thermal oxide layer 108 formed on a trench bottom 106b and trench sidewall 106a of the trench 106, a lower recess-preventing insulator layer 113a formed on the trench thermal oxide layer 108, a nitride liner 110 formed on the lower recess-preventing insulator layer 113a, an upper recess-preventing insulator layer 112a formed on the nitride liner 110, and a trench-burying insulator layer 114 formed on the upper recess-preventing insulator layer 112a to fill up the trench 106.

### Fourth Embodiment

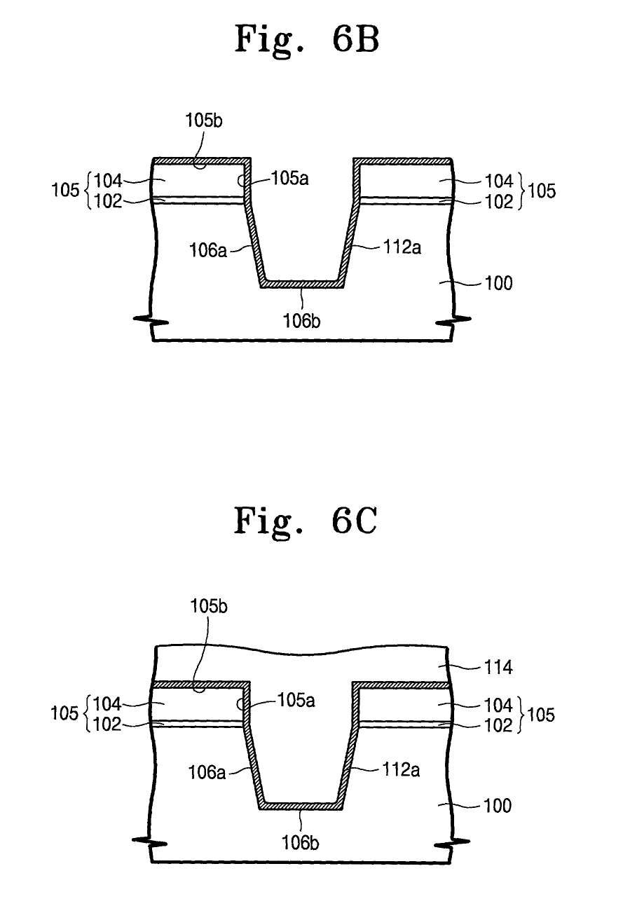

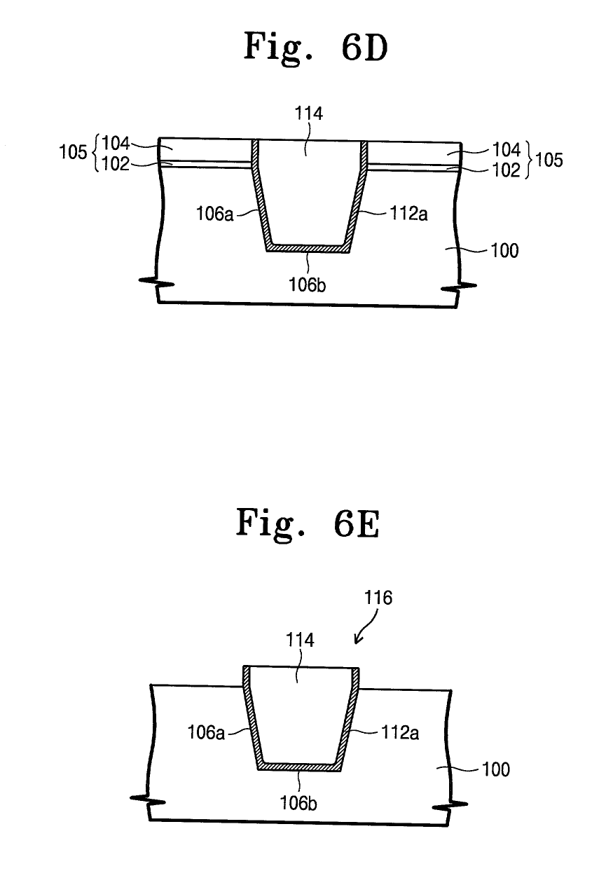

A fourth embodiment of the present invention will now be described hereinafter with reference to FIGS. 6A through 6E, in which the same numerals denote the same elements as the first embodiment. Thus, a description of the same elements will be skipped where appropriate.

In general, the fourth embodiment is different from the first embodiment in that the steps of forming the trench thermal oxide layer 108 and the nitride liner 110 are eliminated. The remainder of the process is similar to that described with regard to the first embodiment.

More specifically, referring now to FIG. 6A, a semiconductor substrate 100 is etched using a trench etch mask 105 to form a trench 106. The trench etch mask 105 is composed of a pad oxide layer 102 and a pad nitride layer 104. Thereafter, a recess-preventing insulator layer 112a is formed on an entire surface of the substrate 100 in which the trench 106 is formed, i.e., on trench sidewall 106a and trench bottom 106b of the trench 106, and a trench etch mask sidewall 105a and a trench etch mask top surface 105b of the trench etch mask. As with the prior embodiments, preferably, the recess-preventing insulator layer 112a is made of thermal oxide. Specifically, a silicon layer 112 is formed as shown in FIG. 6B, and then is subjected to a thermal oxidation process for forming recess-preventing insulator layer 112a. Thus, the silicon layer 112 is transformed into a trench thermal oxide layer. The thermal oxidation process is carried out to alleviate any damage caused by etching of the substrate 100.

Referring now to FIG. 6C, a CVD oxide trench-burying insulator layer 114 is formed on the recess-preventing insulator layer 112a to fill up the trench. Because of the presence of the recess-preventing insulator layer 112a, a high temperature annealing process is not necessary for the CVD oxide trench-burying insulator layer 114.

As shown in FIG. 6D, the pad nitride layer 104 is used as a planarization-stop layer to perform a planarization process on the trench-burying insulator layer 114, such as, for example, a chemical mechanical polishing (CMP) process. The pad nitride layer 104 is then removed using a phosphoric acid solution. The pad oxide layer 102 is then removed in a subsequent cleaning process to form the recess-free trench isolation structure 116, as show in FIG. 6E.

According to the fourth embodiment, a trench isolation structure 116 includes a trench 106 formed in a semiconductor substrate 100, a recess-preventing insulator layer 112a formed on a trench sidewall 106a and trench bottom 106b of the trench 106, and a trench-burying insulator layer 114 formed on the recess-preventing insulator layer 112a to fill up the trench 106.

While illustrative embodiments of the present invention have been shown and described, numerous variations and alternate embodiments will occur to those skilled in the art, without departing from the spirit and scope of the invention. Accordingly, it is intended that the present invention not be limited solely to the specifically described illustrative embodiments. Various modifications are contemplated and can be made without departing from the spirit and scope of the invention as defined by the appended claims.

What is claimed is:

1. A method of forming a trench isolation structure, comprising:
forming a trench etch mask on a semiconductor substrate, the trench etch mask comprising a sequentially formed pad oxide layer and a pad nitride layer;
etching the substrate using the trench etch mask to form a trench therein;
forming a lower recess-preventing insulator layer along the substrate, thereby covering a sidewall and a top surface of the trench etch mask, and a sidewall and a bottom of the trench; and
forming a trench-burying insulator layer on the lower recess-preventing insulator layer to fill up the trench.

2. The method of claim 1, wherein an etch rate of the lower recess-preventing insulator layer is less than an etch rate of the trench-burying insulator layer.

3. The method of claim 2, wherein the lower recess-preventing insulator layer is formed to a thickness of 50 Å to 500 Å.

4. The method of claim 1, further comprising:
planarizing the trench-burying insulator layer until the pad nitride layer is exposed; and
removing the pad nitride layer using an etchant.

5. The method of claim 2, wherein the lower recess-preventing insulator layer is composed of a thermal oxide, formed by,
forming a lower silicon layer on the sidewall and the top surface of the trench etch mask, and on the sidewall and the bottom of the trench; and
performing a thermal oxidation process to thermally oxidize the lower silicon layer.

6. The method of claim 5, wherein the thermal oxidation process is performed at a temperature of 800° C. to 1000° C. in one of an H₂O and O₂ ambient.

7. The method of claim 1, further comprising forming a nitride liner on the lower recess-preventing insulator layer before forming the trench-burying insulator layer.

8. The method of claim 7, further comprising forming an upper recess-preventing insulator layer on the nitride liner before forming the trench-burying insulator layer.

10. The method of claim 8, wherein the upper recess-preventing insulator layer is composed of a thermal oxide, formed by,
forming an upper silicon layer on the nitride liner; and
performing a thermal oxidation process to thermally oxidize the upper silicon layer.

11. The method of claim 1, further comprising forming a trench thermal oxide layer on the sidewall and bottom of the trench, prior to forming the lower recess-preventing insulator layer.

12. A method of forming a trench isolation structure, comprising:
forming a trench etch mask on a semiconductor substrate, the trench etch mask comprising a sequentially formed pad oxide layer and a pad nitride layer;
etching the substrate using the trench etch mask to form a trench therein;
forming a trench thermal oxide layer on a sidewall and a bottom of the trench by employing a thermal oxidation process;
forming a nitride liner on a sidewall and a top surface of the trench etch mask, and on the trench thermal oxide layer;
forming a first silicon layer on the nitride liner;
performing a first silicon thermal oxidation process to transform the first silicon layer into a first recess-preventing insulator layer; and
forming a trench-burying insulator layer on the first recess-preventing insulator layer to fill up the trench.

13. The method of claim 12, wherein the first silicon thermal oxidation process is performed at a temperature of 800° C. to 1000° in one of an H₂O and O₂ ambient.

14. The method of claim 12, wherein the first recess-preventing insulator layer is formed to a thickness of 50 Å to 500 Å.

15. The method of claim 12, further comprising:
planarizing the trench-burying insulator layer until the pad nitride layer is exposed; and
removing the pad nitride layer using an etchant,
wherein an etch rate of the first recess-preventing insulator layer is less than an etch rate of the trench-burying insulator layer.

16. The method of claim 12, wherein after forming the trench thermal oxide layer, and before forming the nitride liner, further comprising:
forming a second silicon layer on a sidewall and a top surface of the trench etch mask, and on the trench thermal oxide layer; and
performing a second silicon thermal oxidation process to transform the second silicon layer into a second recess-preventing insulator layer.

17. The method of claim 16, wherein the second recess-preventing insulator layer is formed to a thickness of 50 Å to 500 Å.

18. The method of claim 16, wherein the second silicon thermal oxidation process is performed at a temperature of 800° C. to 1000° in one of an H₂0 and O₂ ambient.

19. A trench isolation structure comprising:
a trench formed by etching a semiconductor substrate to a predetermined depth;
a first recess-preventing insulator layer formed on a sidewall and a bottom of the trench; and
a trench-burying insulator layer formed on the first recess-preventing insulator layer.

20. The trench isolation structure of claim 19, further comprising a nitride liner underlying the first recess-preventing insulator layer and formed on the sidewall and the bottom of the trench.

21. The trench isolation structure of claim 20, further comprising a trench thermal oxide layer underlying the nitride layer and formed on the sidewall and the bottom of the trench.

22. The trench isolation structure of claim 21, further comprising a second recess-preventing insulator layer formed between the trench thermal oxide layer and the nitride layer.
